(19) United States
(12) Patent Application Publication
(10) Pub. No.: US 2014/0042608 A1
(43) Pub. Date: Feb. 13, 2014

(54) SEMICONDUCTOR PACKAGE AND METHOD OF MANUFACTURING THE SAME

(71) Applicant: Kyung-man KIM, Asan-si (KR)

(72) Inventor: Kyung-man KIM, Asan-si (KR)

(21) Appl. No.: 13/935,475

(22) Filed: Jul. 3, 2013

(30) Foreign Application Priority Data
Aug. 13, 2012 (KR) 10-2012-0088628

(51) Int. Cl. H01L 23/04

(52) U.S. Cl. CPC H01L 23/04
USPC 257/686

(57) ABSTRACT

A semiconductor package is provided with a package on package (PoP) configuration, and which may be implemented having a fine pitch. The semiconductor package can include a lower printed circuit board (PCB) having a top surface onto which at least one lower semiconductor chip is attached; an upper printed circuit board (PCB) disposed on the lower printed circuit board (PCB) and having a top surface onto which at least one upper semiconductor chip is attached; and a lower mold layer formed on the top surface of the lower printed circuit board (PCB) so as to be disposed between the lower printed circuit board (PCB) and the upper printed circuit board (PCB). A through via hole, including a first section formed in the lower mold layer and a second section formed on the first section can also be provided. The through via hole extends through the lower mold layer, and a solder layer is formed in the through via hole to electrically connect the upper printed circuit board (PCB) and the lower printed circuit board (PCB). A horizontal cross-sectional area of the first section of the through via hole varies over substantially an entire height of the first section, and a horizontal cross-sectional area of the second section gradually decreases from a top surface thereof toward an inner portion of the lower mold layer.

### CROSS-REFERENCE TO RELATED APPLICATIONS

This application claims the benefit of Korean Patent Application No. 10-2012-0088628, filed on Aug. 13, 2012, in the Korean Intellectual Property Office, the disclosure of which is incorporated herein in its entirety by reference.

### BACKGROUND

The inventive concepts relate to a semiconductor package, and more particularly, to a semiconductor package having a package on package (PoP) structure.

As the electronics industry has become more developed and user's needs have increased, electronic devices have become smaller and more lightweight with increasing functionality. Thus, because semiconductor devices are essential components of electronic devices, they have also needed to become more highly integrated. In addition, because of the high demand for smaller and more functional mobile products, there has been an increasing demand for the miniaturization of semiconductor devices with increasing multi-function capabilities.

Thus, in order to provide smaller, multi-functional semiconductor packages, significant research has been put into semiconductor packages having a package on package (PoP) structure—in which a semiconductor package having one function is stacked on a semiconductor package having a different function. Unfortunately, however, as the number of vias for connection between the upper and lower packages of a PoP semiconductor package increases, the size of the PoP semiconductor package also increases.

### SUMMARY

The inventive concepts provide a semiconductor package having a package on package (PoP) structure which may be implemented having a fine pitch.

According to an aspect of the inventive concepts, a semiconductor package can comprise a lower printed circuit board (PCB) having a top surface onto which at least one lower semiconductor chip is attached, an upper printed circuit board disposed above the lower printed circuit board and having a surface onto which at least one upper semiconductor chip is attached. A lower mold layer can be formed on the top surface of the lower printed circuit board so as to be disposed between the lower printed circuit board and the upper printed circuit board, and a through via hole can be formed to penetrate through the lower mold layer. The through via hole can comprise a first segment space (or section) formed in the lower mold layer and a second segment space (or section) formed on the first segment space. A solder layer can be formed in the through via hole to electrically connect the upper printed circuit board and the lower printed circuit board. A horizontal cross-sectional area of the first section may vary over substantially an entire height of the first section, and a horizontal cross-sectional area of the second section may gradually decrease from a top portion thereof to an inner portion of the lower mold layer.

A horizontal cross-sectional area of a the first section may be greatest at a top thereof, and the horizontal cross-sectional area of the first section may gradually decrease from the top portion to a bottom portion thereof.

The horizontal cross-sectional area of the through via hole may gradually increase at an interface between the first and second sections and may gradually decrease from a top portion to a bottom portion of the first section.

A horizontal cross-sectional area of the first section may be smallest at a bottom portion of the first section.

The solder layer may fill substantially all of the first section.

The solder layer may fill only a portion of the second section.

A vacancy may be formed in the second section along an upper edge of the solder layer.

Another vacancy may be formed in the second section along a lower edge of the solder layer.

The through via hole may include the first and second sections, and may further comprise at least one third section filled by the solder layer. A horizontal cross-sectional area of each of the at least one third section may vary over substantially an entire height of each of the third sections.

A height of a top portion of the first section may be substantially the same as a height of the top surface of the at least one lower semiconductor chip with respect to the top surface of the lower printed circuit board.

At least one lower semiconductor chip and the lower printed circuit board, or at least one upper semiconductor chip and the upper printed circuit board may be electrically connected using a wire bonding method or a flip chip method.

The at least one lower semiconductor chip may comprise a plurality of lower semiconductor chips. The plurality of lower semiconductor chips may comprise a first lower semiconductor chip and a second lower semiconductor chip stacked on the first lower semiconductor chip, and the second lower semiconductor chip may be electrically connected to the lower printed circuit board via a through electrode extending through the first lower semiconductor chip.

A top surface of at least one of the lower semiconductor chips may be exposed by the lower mold layer.

The lower mold layer and the upper printed circuit board may be spaced apart from each other so that a gap exists between the lower mold layer and the upper printed circuit board.

According to another aspect of the inventive concepts, a semiconductor package can comprise a lower package comprising a lower printed circuit board, at least one lower semiconductor chip attached onto the lower printed circuit board, and a lower mold layer formed on the lower printed circuit board to surround at least a portion of the at least one lower semiconductor chip. A through via hole can be formed through the lower mold layer. An upper package attached onto the lower package can comprise an upper printed circuit board, at least one upper semiconductor chip attached onto the upper printed circuit board, and an upper mold layer formed on the upper printed circuit board and surrounding the at least one upper semiconductor chip. A solder layer can be provided in the through via hole to electrically connect the upper printed circuit board and the lower printed circuit board. The through via hole can comprise a plurality of sections connected together to extend through the lower mold layer. A horizontal cross-sectional area of the through via hole can increase at a boundary between the sections. The solder layer extends through the through via hole and can fill substantially all of a via hole section arranged adjacent to the lower printed circuit board. A horizontal cross-sectional area of a top section of the plurality of sections gradually decreases from a top surface thereof toward an inner portion of the lower mold layer.

According to further aspects of the inventive concepts, a semiconductor package can comprise a lower package comprising a lower printed circuit board (PCB), at least one lower semiconductor chip attached onto the lower printed circuit board (PCB), and a lower mold layer formed on the lower printed circuit board (PCB), surrounding at least a part of the at least one lower semiconductor chip. A through via hole can be formed in the lower mold layer. An upper package may be attached onto the lower package and comprise an upper printed circuit board (PCB), at least one upper semiconductor chip attached onto the upper printed circuit board (PCB), and an upper mold layer formed on the upper printed circuit board (PCB) and surrounding the at least one upper semiconductor chip. A solder layer arranged in the through via hole electrically connects the upper printed circuit board (PCB) and the lower printed circuit board (PCB).

The through via hole may extend through the lower mold layer and comprise a cross-sectional area that varies along its height. The through via hole may further comprise a plurality of different diameters including at least a first diameter, a second diameter, a third diameter, and a fourth diameter. The cross-sectional area may comprise the first diameter near a top of the through via hole and taper inwardly towards an interior of the lower mold layer until it comprises the second diameter. The second diameter may be smaller than the first diameter. The cross-sectional area of the through via hole may expand from the second diameter to the third diameter, said third diameter being larger than the second diameter. The cross-sectional area may then taper gradually from the third diameter to the fourth diameter, said fourth diameter being smaller than the third diameter and being arranged near a bottom of the through via hole.

In one embodiment, the cross-sectional area of the through via hole may expand gradually in a downward direction from the second diameter to the third diameter, and a sidewall of the through via hole may have a somewhat convex cross-sectional shape between the second diameter and the third diameter.

In another embodiment, the cross-sectional area of the through via may expand substantially immediately from the second diameter to the third diameter, such that a sidewall of the through via hole has a substantially flat horizontal cross-sectional shape between the second diameter and the third diameter.

In a still further embodiment, an outermost diameter of the through via hole may expand gradually in an upward direction from the second diameter to the third diameter, such that a sidewall of the through via has a somewhat concave cross-sectional shape between the second diameter and the third diameter.

The solder layer may fill substantially all of the cross-sectional area of the through via hole between the third diameter and the fourth diameter, but may fill less than the entire cross-sectional area of the through via hole between the first diameter and the second diameter.

### BRIEF DESCRIPTION OF THE DRAWINGS

Exemplary embodiments of the present inventive concepts will be more clearly understood from the following detailed description, when taken in conjunction with the accompanying drawings, in which:

FIGS. 1 through 9 are schematic cross-sectional views of a semiconductor package during various stages of manufacture, illustrating operations of manufacturing the semiconductor package, according to an exemplary embodiment of the inventive concepts, where, more specifically;

FIG. 1 is a schematic cross-sectional view of a partially constructed semiconductor package illustrating an operation of attaching a lower semiconductor chip onto a lower printed circuit board (PCB), according to an exemplary embodiment of the inventive concepts;

FIG. 2 is a schematic cross-sectional view of a partially constructed semiconductor package illustrating an operation of forming a first lower mold layer according to an embodiment of the inventive concepts;

FIG. 3 is a schematic cross-sectional view of a partially constructed semiconductor package illustrating an operation of forming a first through hole according to an embodiment of the inventive concepts;

FIG. 4 is a schematic cross-sectional view of a partially constructed semiconductor package illustrating an operation of forming a first solder layer according to an embodiment of the inventive concepts;

FIG. 5 is a schematic cross-sectional view of a partially constructed semiconductor package illustrating an operation of reflowing the first solder layer according to an embodiment of the inventive concepts;

FIG. 6 is a schematic cross-sectional view of a partially constructed semiconductor package illustrating an operation of forming a second lower mold layer according to an embodiment of the inventive concepts;

FIG. 7 is a schematic cross-sectional view of a partially constructed semiconductor package illustrating an operation of forming a second through hole according to an embodiment of the inventive concepts;

FIG. 8 is a schematic cross-sectional view of a partially constructed semiconductor package illustrating an operation of forming a second solder layer according to an embodiment of the inventive concepts;

FIG. 9 is a schematic cross-sectional view of a semiconductor package illustrating an operation of forming a semiconductor package by mounting an upper package on a lower package, according to an embodiment of the inventive concepts;

FIG. 10 is a schematic cross-sectional view of a partially constructed semiconductor package illustrating an operation of forming a semiconductor package according to a modified example of FIG. 9;

FIG. 11 is a schematic cross-sectional view of a semiconductor package according to a modified example of FIG. 9;

FIG. 12 is a schematic cross-sectional view of a partially constructed semiconductor package illustrating an operation of forming a first solder layer according to another embodiment of the inventive concepts;

FIG. 13 is a schematic cross-sectional view of a partially constructed semiconductor package illustrating an operation of reflowing the first solder layer according to another embodiment of the inventive concepts;

FIG. 14 is a schematic cross-sectional view of a partially constructed semiconductor package illustrating an operation of forming a second lower mold layer according to another embodiment of the inventive concepts;

FIG. 15 is a schematic cross-sectional view of a semiconductor package illustrating an operation of forming a semiconductor package according to another embodiment of the inventive concepts;

FIG. 16 is a schematic cross-sectional view of a partially constructed semiconductor package illustrating an operation of forming a first lower mold layer according to another embodiment of the inventive concepts;

FIG. 17 is a schematic cross-sectional view of a partially constructed semiconductor package illustrating an operation of forming a first through hole and a first solder layer according to an embodiment of the inventive concepts;

FIG. 18 is a schematic cross-sectional view of a partially constructed semiconductor package illustrating an operation of forming a third lower mold layer and a third through hole after the first solder layer is reflowed, according to an embodiment of the inventive concepts;

FIG. 19 is a schematic cross-sectional view of a partially constructed semiconductor package illustrating an operation of forming a second lower mold layer, a second through hole, and a second solder layer after a third solder layer is formed so as to be reflowed to the third through hole, according to another embodiment of the inventive concepts;

FIG. 20 is a schematic cross-sectional view of a semiconductor package illustrating an operation of forming a semiconductor package by mounting an upper package on a lower package, according to another embodiment of the inventive concepts;

FIG. 21 is a schematic cross-sectional view of a partially constructed semiconductor package illustrating an operation of forming a first lower mold layer after a lower semiconductor chip is attached onto a lower PCB, according to another embodiment of the inventive concepts;

FIG. 22 is a schematic cross-sectional view of a partially constructed semiconductor package illustrating an operation of forming a first through hole according to another embodiment of the inventive concepts;

FIG. 23 is a schematic cross-sectional view of a partially constructed semiconductor package illustrating an operation of forming a second lower mold layer after the first solder layer is formed and is reflowed, according to another embodiment of the inventive concepts;

FIG. 24 is a schematic cross-sectional view of a semiconductor package illustrating an operation of forming a semiconductor package by mounting an upper package on a lower package after the second through hole and the second solder layer are formed, according to another embodiment of the inventive concepts;

FIG. 25 is a schematic cross-sectional view of a semiconductor package illustrating a semiconductor package according to another embodiment of the inventive concepts;

FIG. 26 is a schematic cross-sectional view of a semiconductor package illustrating a semiconductor package according to another embodiment of the inventive concepts;

FIG. 27 is a schematic cross-sectional view of a semiconductor package illustrating a semiconductor package according to another embodiment of the inventive concepts;

FIG. 28 is a schematic cross-sectional view of a semiconductor package illustrating a semiconductor package according to another embodiment of the inventive concepts;

FIG. 29 is a schematic cross-sectional view of a semiconductor package illustrating a semiconductor package according to another embodiment of the inventive concepts;

FIG. 30 is a schematic cross-sectional view of a semiconductor package illustrating a semiconductor package according to another embodiment of the inventive concepts; and

FIG. 31 provides schematic cross-sectional views of various shapes of through via holes according to additional embodiments of the inventive concepts.

### DETAILED DESCRIPTION OF THE EMBODIMENTS

The attached drawings illustrate exemplary embodiments of the inventive concepts and are referred to in order to provide a sufficient understanding of the inventive concepts, the merits thereof, and the objectives accomplished by the implementation of the inventive concepts. The inventive concepts may, however, be embodied in many different forms and should not be construed as being limited to the specific embodiments set forth herein. Rather, these embodiments are provided so that this disclosure will be thorough and complete, and will fully convey the principles of the inventive concepts to those skilled in the art. In the drawings, elements may be enlarged compared to their actual sizes for convenience of explanation, and size ratios between the elements may be exaggerated or reduced.

It will be understood that when an element, such as a layer, a region, or a substrate, is referred to as being “on,” “connected to” or “coupled to” another element, it may be directly on, connected or coupled to the other element, or intervening elements may be present. In contrast, when an element is referred to as being “directly on,” “directly connected to” or “directly coupled to” another element or layer, there are no intervening elements or layers present. This applies to interpretation of other expressions for describing the relationship between elements, i.e., “between” and “directly between”, or “adjacent to” and “directly adjacent to.”

It will be understood that, although the terms “first,” “second,” “third,” etc. may be used herein to describe various elements, components, regions, layers and/or sections, these elements, components, regions, layers and/or sections should not be limited by these terms. These terms refer to a particular order, rank, or superiority and are only used to distinguish one element, component, region, layer or section from another element, component, region, layer or section. Thus, a first element, component, region, layer or section discussed below could be termed a second element, component, region, layer or section without departing from the teachings of the example embodiment. For example, a first element may be referred to as a second element, and similarly, a second element may be referred to as a first element without departing from the scope of protection that should be afforded to the inventive concepts.

As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

The terms used herein may be interpreted according to the meanings that are well-known to those of ordinary skill in the art if the terms are not otherwise defined herein.

Various exemplary embodiments of the inventive concepts will now be described more fully with reference to the accompanying drawings.

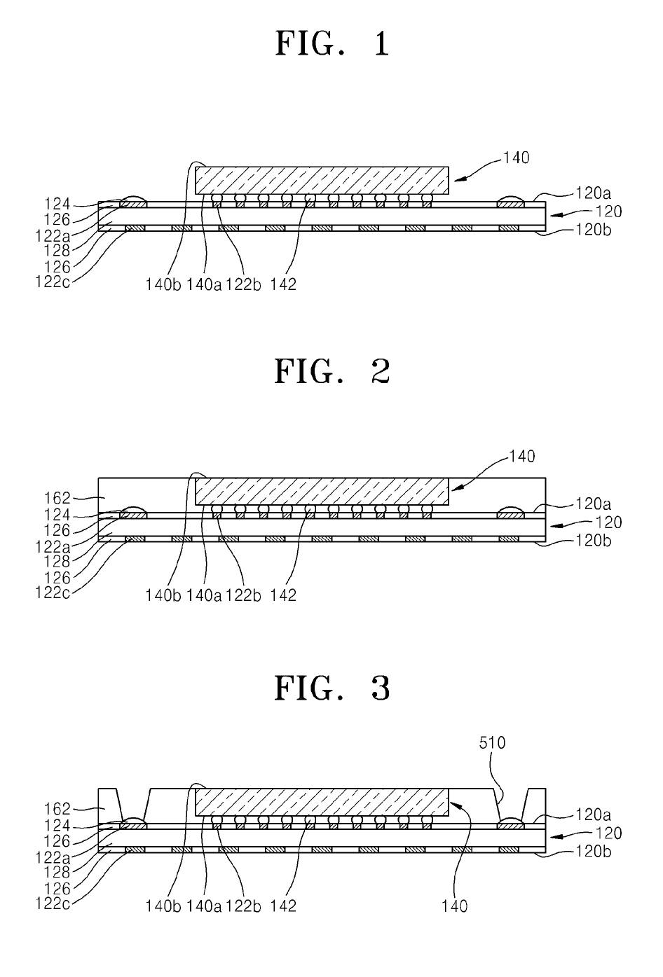

FIGS. 1 through 9 are schematic cross-sectional views illustrating a semiconductor package and operations of manufacturing the semiconductor package, according to an exemplary embodiment of the inventive concepts.

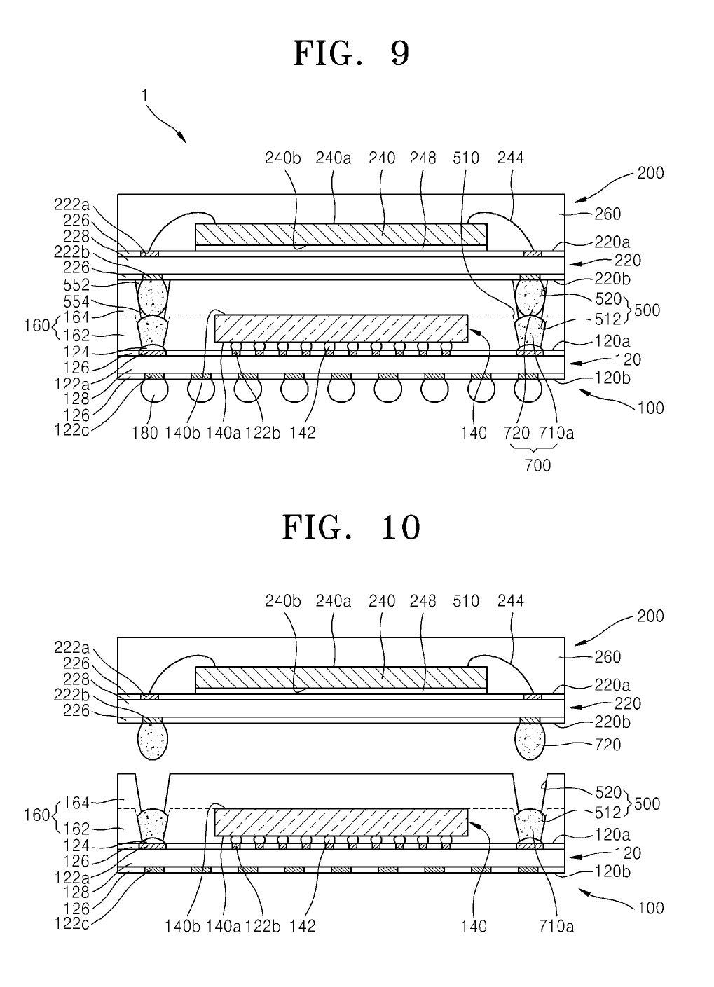

FIG. 1 is a schematic cross-sectional view illustrating a first step in the manufacture of the semiconductor package 1 of FIG. 9. More particularly, FIG. 1 illustrates an operation of attaching a lower semiconductor chip 140 onto a lower printed circuit board (PCB) 120.

Referring to FIG. 1, a lower semiconductor chip 140 is attached onto the lower PCB 120. First and second lower connection pads 122a and 122b, which are exposed by a solder resist layer 126, may be formed on a top surface 120a of the lower PCB 120. A third lower connection pad 122c may be formed on a bottom surface 120b of the lower PCB 120. The first lower connection pad 122a may be formed in an outer edge area of the top surface 120a of the lower PCB 120, which is not covered by the lower semiconductor chip 140. The second lower connection pad 122b may be formed in an inner area of the top surface 120a of the lower PCB 120, so as to be covered by the lower semiconductor chip 140. The second lower connection pad 122b, however, may also be formed in the outer edge area of the top surface 120a of the lower PCB 120, depending on the method used for attaching the lower semiconductor chip 140.

A lower base substrate 128 may be formed of a single layer or of a plurality of stacked thin substrates. The lower base substrate 128 may be formed of an insulation material. The insulation material can, for example, be a rigid material, such as Bismaleimide Triazine (BT) resin or Frame Retardant 4 (FR4), or a flexible material, such as Poly Imide (PI) or Poly EsTer (PET).

The first through third lower connection pads 122a, 122b, and 122c may be exposed by the solder resist layer 126 formed on the top surface 120a and the bottom surface 120b of the lower PCB 120, respectively. The first through third lower connection pads 122a, 122b, and 122c may be formed of a metal such as copper (Cu), or by plating another metal or other material, such as nickel (Ni) and/or gold (Au), on patterns formed of metal, such as copper (Cu).

Although not shown, the first and second lower connection pads 122a and 122b and the third lower connection pad 122c may be electrically connected to one another via a conductive path formed in the lower base substrate 128.

An adhesive solder layer 124 may optionally be formed on the first lower connection pad 122a. A solder layer that is the same as or similar to the adhesive solder layer 124, may further be formed on the second and third lower connection pads 122b and 122c. The adhesive solder layer 124 may be conductive to facilitate electrical connection, as well as providing an adhesive force, with a member connected to the first lower connection pad 122a. The adhesive solder layer 124 need not be formed, however.

The lower semiconductor chip 140 can have an active face 140a and a non-active face 140b. An integrated circuit (IC) including unit active and passive elements may be formed on the active face 140a. The lower semiconductor chip 140 may include, for example, a highly-integrated circuit semiconductor memory device, such as a dynamic random access memory (DRAM), a static RAM (SRAM), a flash memory, a processor, such as a Central Processor Unit (CPU), a Digital Signal Processor (DSP), a combination of a CPU and a DSP, or an individual semiconductor device, such as an Application Specific Integrated Circuit (ASIC), a Micro Electro Mechanical System (MEMS), or an optoelectronic device, or other desired circuitry. The lower semiconductor chip 140 may be formed, for instance, by separating a semiconductor wafer into separate chips after being background or back lapped following formation of an IC on the semiconductor wafer (not shown). Although, in the embodiment shown, one lower semiconductor chip 140 is attached onto the lower PCB 120, two or more lower semiconductor chips 140 may be stacked on the lower PCB 120.

The lower semiconductor chip 140 may be mounted on the lower PCB 120 using a flip chip method so that the active face 140a faces the lower PCB 120. In this case, the non-active face 140b of the lower semiconductor chip 140 may be referred to as a “top surface” of the lower semiconductor chip 140. On the other hand, when the non-active face 140b of the lower semiconductor chip 140 is mounted to face the lower PCB 120, the active face 140a of the lower semiconductor chip 140 may be referred to as the “top surface” of the lower semiconductor chip 140. In other words, the term “bottom surface,” when referring to an element that may be mounted on the lower PCB 120, typically refers to the surface that faces the lower PCB 120, while the term “top surface” typically refers to the other surface that faces away from the lower PCB 120 of the element.

The lower semiconductor chip 140 may be electrically connected to the lower PCB 120 through a plurality of second lower connection pads 122b and a plurality of lower connection members 142 that correspond to one another. The lower connection members 142 may, for example, be a solder ball, a bump, or the like.

FIG. 2 is a schematic cross-sectional view of a partially formed semiconductor package 1 of FIG. 9, illustrating an operation of forming a first lower mold layer 162 according to another aspect of the inventive concepts.

Referring to FIG. 2, a first lower mold layer 162 can be formed on the lower PCB 120 so as to cover the lower PCB 120. The first lower mold layer 162 may, for instance, be formed of Epoxy Mold Compound (EMC), for example. The first lower mold layer 162 may cover sides of the lower semiconductor chip 140 while exposing the non-active face 140b of the lower semiconductor chip 140, such that a top surface of the first lower mold layer 162 and a top surface of the non-active face 140b of the lower semiconductor chip 140 may be arranged at the same height. Alternatively, the first lower mold layer 162 may only partially cover the sides of the lower semiconductor chip 140 so that the top surface of the first lower mold layer 162 may be lower than the non-active face 140b of the lower semiconductor chip 140. In yet another configuration, the lower mold layer 162 may cover the non-active face 140b of the lower semiconductor chip 140 so that the top surface of the first lower mold layer 162 may be arranged higher than the non-active face 140b of the lower semiconductor chip 140.

FIG. 3 is a schematic cross-sectional view of a partially constructed semiconductor package 1 of FIG. 9, illustrating an operation of forming a first through hole 510 according to another aspect of the inventive concepts.

Referring to FIG. 3, a first through hole 510 can be formed to penetrate the first lower mold layer 162. The first through hole 510 may be formed, for instance, by removing a part of the first lower mold layer 162 using an etching process or a laser drilling method. Alternatively, the first through hole 510 may be formed during formation of the first lower mold layer 162, for instance, by using a mold that includes a shape to form the first through hole 510. An surface of the first lower mold layer 162 that forms a sidewall of the first through hole 510, may have an inclination angle with respect to a direction perpendicular to the top surface of the lower PCB 120. Thus, the first through hole 510 may be formed in such a way that a horizontal cross-sectional area of the first through hole 510 gradually decreases from the top surface of the first lower mold layer 162 toward the top surface of the PCB 120. As used herein, the phrase “horizontal cross-sectional area” refers to an area of a cross-section that is cut along a surface parallel to the top surface 120a of the lower PCB 120. The first through hole 510 may be formed, for example, to have a circular, oval, or polygonal horizontal cross-sectional area. Thus, the horizontal cross-sectional area may depend on the height of the first through hole 510, and may be proportional to a square of a width at any given height. Thus, although the drawings provide only longitudinal cross-sectional views, it will be clear to one of ordinary skill in the art that the horizontal cross-sectional area may be proportional to the square of the width and thus, latitudinal cross-sectionals views are omitted herein for simplicity.

The first through hole 510 may be formed to expose a portion of the lower PCB 120. In particular, the first through hole 510 may be formed so that the adhesive solder layer 124 or the lower connection pad 122a of the lower PCB 120 may be exposed.

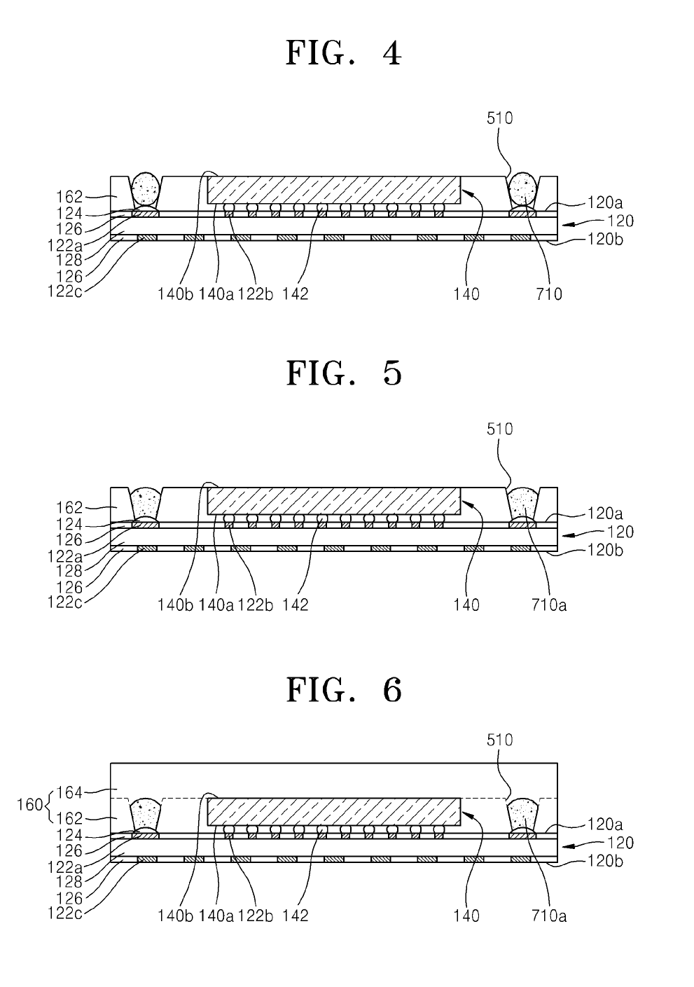

FIG. 4 is a schematic cross-sectional view of a partially constructed semiconductor package 1 of FIG. 9, illustrating an operation of forming a first solder layer 710 according to another aspect of the inventive concepts.

Referring to FIG. 4, a first solder layer 710 may be formed in the first through hole 510. The first solder layer 710 may be formed, for instance, by injecting a solder paste into the first through hole 510 using screen printing, solder jetting, or by picking and placing solder balls in the first through hole 510. The amount of solder paste injected into the first through hole 510 or the sizes of solder balls placed in the first through hole 510 may be determined or adjusted based on the result of reflowing the first solder layer 710.

FIG. 5 is a schematic cross-sectional view of a partially constructed semiconductor package 1 of FIG. 9, illustrating an operation of reflowing the first solder layer 710 according to another aspect of the inventive concepts.

Referring to FIG. 5, the first solder layer 710a may be reflowed and formed by a reflow process performed by applying heat to the first solder layer 710. The reflowed first solder layer 710a may fill the lower area of the first through hole 510, and an upper surface of the reflowed first solder layer 710a may have a convex shape due to surface tension. A top of the upper surface of the reflowed first solder layer 710a may have the same height as the top surface of the first lower mold layer 162 or a height that is lower than the top surface of the first lower mold layer 162. Alternatively, the top of the upper surface of the reflowed first solder layer 710a may have the same height as the top surface of the first lower mold layer 162, or may protrude above the top surface of the first lower mold layer 162. The amount of the solder paste injected into the first through hole 510 or the sizes of the solder balls injected into the first through hole 510 may be selected in consideration of the desired height of the reflowed first solder layer 710a.

FIG. 6 is a schematic cross-sectional view of a partially constructed semiconductor package 1 of FIG. 9, illustrating an operation of forming a second lower mold layer 164 according to another aspect of the inventive concepts.

Referring to FIG. 6, a second lower mold layer 164 can be formed on the first lower mold layer 162. The second lower mold layer 164 may be formed to cover all of the reflowed first solder layer 710a, the first through hole 510, and the lower semiconductor chip 140. A portion of the first through hole 510 that is not filled by the first solder layer 710a, may be filled by the second lower mold layer 164. The second lower mold layer 164 may be formed of EMC, for example.

When the first lower mold layer 162 and the second lower mold layer 164 are formed of the same material, a boundary between the first lower mold layer 162 and the second lower mold layer 164 may not be detectable, and the first lower mold layer 162 and the second lower mold layer 164 may collectively be referred to as a lower mold layer 160.

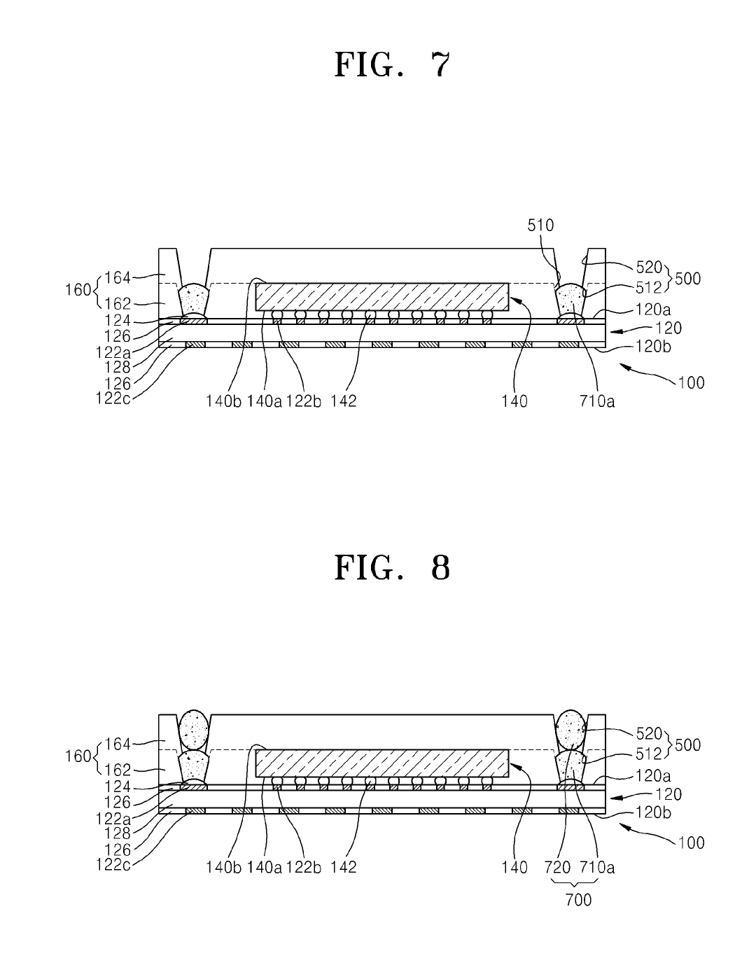

FIG. 7 is a schematic cross-sectional view of a partially constructed semiconductor package 1 of FIG. 9, illustrating an operation of forming a second through hole 520 according to another aspect of the inventive concepts.

Referring to FIG. 7, a second through hole 520 may be formed to expose the reflowed first solder layer 710a by penetrating the lower mold layer 160. The second through hole 520 may, for instance, be formed by removing a part of the second lower mold layer 164 using an etching process or a laser drilling method, for example. Alternatively, the second through hole 520 may be formed while forming the second lower mold layer 164 by using mold having a shape configured to form the second through hole 520. As with the first through hole 510, surface of the lower mold layer 160 that forms a sidewall of the second through hole 520 may have an inclination angle with respect to a direction perpendicular to the top surface of the lower PCB 120. Thus, the second through hole 520 may also be formed such that that a horizontal cross-sectional area of the second through hole 520 gradually decreases from the top surface of the lower mold layer 160 to the top surface of the lower semiconductor chip 140, or toward the top surface of the lower PCB 120.

A space formed by the sidewalls of the lower mold layer 160 that surround the surface of the reflowed first solder layer 710a may be referred to as a first through via hole 512. In some embodiments, since a portion of the first through hole 510 that is not completely filled by the reflowed first solder layer 710a is filled by a part of the second lower mold layer 164, the portion of the first through hole 510 excluding the portion filled by the part of the second lower mold layer 164 provides the first through via hole 512. The first through via hole 512 and the second through hole 520 may collectively be referred to as a through via hole 500.

FIG. 8 is a schematic cross-sectional view of a partially constructed semiconductor package 1 of FIG. 9, illustrating an operation of forming a second solder layer 720 according to another aspect of the inventive concepts.

Referring to FIG. 8, a second solder layer 720 is formed in the second through hole 520. The second solder layer 720 may be formed by injecting a solder paste into the second through hole 520 using screen printing or solder jetting, or by picking and placing solder balls in the second through hole 520. The second solder layer 720 may be electrically connected to the reflowed first solder layer 710a. A top of the upper surface of the second solder layer 720 may have the same height as the top surface of the second lower mold layer 164, may protrude from the top surface of the second lower mold layer 164, or may be recessed below the top surface of the second lower mold layer 164.

The reflowed first solder layer 710a and the second solder layer 720 may collectively be referred to as a solder layer 700. The solder layer 700 may be formed via the through via hole 500 and may be electrically connected to the lower PCB 120.

The lower PCB 120, the lower semiconductor chip 140, and the lower mold layer 160 may collectively be referred to as a lower package 100. The through via hole 500 may be formed in the lower mold layer 160 of the lower package 100, and the solder layer 700, which is electrically connected to the lower PCB 120, may be formed in the through via hole 500.

FIG. 9 is a schematic cross-sectional view of a semiconductor package 1, formed by mounting an upper package 200 on the lower package 100, according to an embodiment of the inventive concepts.

Referring to FIG. 9, a semiconductor package 1 can be formed by mounting an upper package 200 on the lower package 100, constructed as described above. The upper package 200 may include an upper PCB 220, an upper semiconductor chip 240 attached to the upper PCB 220, and an upper mold layer 260 that surrounds the upper semiconductor chip 240.

The upper PCB 220 may include a first upper connection pad 222a and a second upper connection pad 222b that are formed on a top surface 220a and a bottom surface 220b of the upper PCB 220, respectively. The first and second upper connection pads 222a and 222b are exposed by a solder resist layer 226. The first upper connection pad 222a may be formed in an area of the top surface 220a of the upper PCB 220 outside of an area covered by the upper semiconductor chip 240. However, the second upper connection pad 222b may alternatively be formed in an area of the top surface 220a of the upper PCB 220 covered by an upper semiconductor chip 240, depending on a method of attaching the upper semiconductor chip 240.

An upper base substrate 228 may be formed of a single layer or a plurality of stacked thin substrates. The upper base substrate 228 may be formed of an insulation material.

The first and second upper connection pads 222a and 222b may be exposed by the solder resist layer 226 formed on the top surface 220a and the bottom surface 220b of the upper PCB 220, respectively. The first upper connection pad 222a and the second upper connection pad 222b may be electrically connected to each other via a conductive path formed in the upper base substrate 228.

The upper semiconductor chip 240 may have an active face 240a and a non-active face 240b. An IC including unit active and passive elements may be formed on the active face 240. The upper semiconductor chip 240 may include, for example, a highly-integrated circuit semiconductor memory device such as a DRAM, an SRAM, or a flash memory, a processor such as a CPU, a DSP, or a combination of a CPU and a DSP, or an individual semiconductor device, such as an ASIC, a MEMS, or an optoelectronic device. Although one upper semiconductor chip 240 is shown attached onto the upper PCB 220, two or more upper semiconductor chips 140 may be stacked on the upper PCB 220.

The upper semiconductor chip 240 may be mounted on the upper PCB 220 in a state where an upper adhesive layer 248 is interposed between the upper semiconductor chip 240 and the upper PCB 220 with the non-active face 240b facing the upper PCB 220. In this case, the active face 240a of the upper semiconductor chip 240 may be referred to as a top surface of the upper semiconductor chip 240. The upper semiconductor chip 240 may be electrically connected to the upper PCB 220 through a wire bonding method using upper bonding wires 244. The upper bonding wires 244 may be formed to connect a pad formed on the active face 240a of the upper semiconductor chip 240 and the first upper connection pad 222a formed on the top surface 220a of the upper PCB 220.

The upper mold layer 260 may be formed on the upper PCB 220 so as to cover the upper semiconductor chip 240 and the upper bonding wires 244. The upper mold layer 260 may be formed of EMC, for example.

The upper package 200 may be attached onto the lower package 100 so that the second upper connection pad 222b that is formed on the bottom surface 220b of the upper PCB 220 and the solder layer 700 contact each other. Although not shown, a solder material that is similar to the adhesive solder layer 124 formed on the first lower connection pad 122a of the lower PCB 120, may be further deposited on the second upper connection pad 222b. In order to improve electrical connection and an adhesive force between the second upper connection pad 222b and the solder layer 700, heat treatment may be performed after the upper package 200 is attached onto the lower package 100. The solder layer 700 may perform the function of a via to electrically connect the upper package 200 and the lower package 100.

In summary, the semiconductor package 1 can include a lower PCB 120 having a top surface 120a onto which a lower semiconductor chip 140 is attached, and an upper PCB 220 that is disposed above the lower PCB 120. The upper PCB 220 has a top surface 220a onto which an upper semiconductor chip 240 is attached. A lower mold layer 160 is formed on the top surface 120a of the lower PCB 120 so as to be disposed between the lower PCB 120 and the upper PCB 220, with a through via hole 500 formed in the lower mold layer 160 to penetrate through the lower mold layer 160. A solder layer 700 is formed in the through via hole 500 to electrically connect the upper PCB 220 and the lower PCB 120.

A horizontal cross-sectional area of the through via hole 500 may vary along its height. In addition, the through via hole 500 may be divided into a plurality of segments. In each segment, the horizontal cross-sectional area of the through via hole 500 may gradually decrease. The first through via hole 512 and the second via hole 520, for example, may correspond to two separate sections, respectively, and may be referred to as a first section 512 and a second section 520.

A horizontal cross-sectional area of the first section 512 may vary along the height of the first section 512. For example, the horizontal cross-sectional area of the first section 512 may increase quickly along its convex top surface and then gradually decrease from the top surface (i.e., arranged at or near a boundary between the first section 512 and the second section 520) to the bottom (i.e., arranged at or near the top surface of the lower PCB 120). Thus, the horizontal cross-sectional area of the first section 512 may be at a minimum at the top and/or bottom of the first section 512.

A reflowed first solder layer 710a that is a part of the solder layer 700, may fill the entirety of the first section 512. Since a portion of the first through hole 510 illustrated in FIG. 5 excluding the reflowed first solder layer 710a is filled by the second lower mold layer 164, the first section 512 may have a convex top surface that coincides with the top surface of the reflowed first solder layer 710a.

In an embodiment where the top of the top surface of the reflowed first solder layer 710a has the same height as the top surface of the first lower mold layer 162, and where the top surface of the first lower mold layer 162 and the top surface 140b of the lower semiconductor chip 140 have the same height, the height of the first section 512 may be the same as the height of the lower semiconductor chip 140 with respect to the top surface 120a of the lower PCB 120.

A horizontal cross-sectional area of the second section 520 may gradually decrease from the top (i.e., arranged at or near the top surface of the lower mold layer 160) to the bottom (i.e., arranged at or near the middle of the lower mold layer 160, or the top of the reflowed first solder layer 710a). Thus, the horizontal cross-sectional area of the second section 520 may be at a minimum at its bottom.

The second solder layer 720 that is a part of the solder layer 700, may fill only a part of the second section 520. When an additional process of filling a vacancy is not performed after the second solder layer 720 is formed in the second through hole (or second section) 520, only part of the second section 520 is filled by the solder layer 700. Vacancies 552 and 554 may thereby be formed in the second section 520. More particularly, a first vacancy 552 may be formed in the second section 520 along the upper edge portion of the solder layer 720 and a second vacancy 554 may be formed in the second section 520 along the lower edge portion of the solder layer 720.

An insulation material that is different from the material used to form the lower mold layer 160, may be used to fill either the first vacancy 552, the second vacancy 554, or both.

The first lower mold layer 162 and the second lower mold layer 164 (which together constitute the lower mold layer 160), may have the same or similar thicknesses. In this case, the first vacancy 552 and the second vacancy 554 may have the same or similar heights. Alternatively, the second lower mold layer 164 may have a larger thickness than the first lower mold layer 162. In this case, the second vacancy 554 may have a larger height than the first vacancy 552.

Hereinafter, modified examples or alternative embodiments of the semiconductor package and the method of manufacturing the same illustrated in FIGS. 1 through 9 will be illustrated and described. Since the modified embodiments may involve many of the same or similar steps, redundant descriptions are omitted from the following description.

FIG. 10 is a schematic cross-sectional view of a partially constructed semiconductor device 1 of FIG. 9, illustrating an operation of forming a semiconductor package by mounting an upper package 200 on a lower package 100 according to a modified example of FIG. 9. More particularly, FIG. 10 illustrates operations which may be used following those described previously with respect to FIG. 7.

Referring to FIG. 10, the upper package 200 can be mounted on the lower package 100. Unlike FIG. 8, however, a second solder layer 720 may be first attached onto the upper package 200. The second solder layer 720 may, for instance, be attached onto a bottom surface 220b of an upper PCB 220. For example, the second solder layer 720 may be attached onto the bottom surface 220b of the upper PCB 220 so as to be electrically connected to a second lower connection pad 222b that is exposed by a solder resist 226.

The upper package 200 may be attached onto the lower package 100 by inserting the second solder layer 720 into a second through hole 520. When the upper package 200 is attached onto the lower package 100, the second solder layer 720 may contact a reflowed first solder layer 710a and may be electrically connected to the reflowed first solder layer 710a as illustrated in FIG. 9. Thus, the semiconductor package 1 illustrated in FIG. 9 may be formed using this alternative method. In order to improve electrical connection and an adhesive force between the second solder layer 720 and the reflowed first solder layer 710a, heat treatment may be performed after the upper package 200 is attached onto the lower package 100.

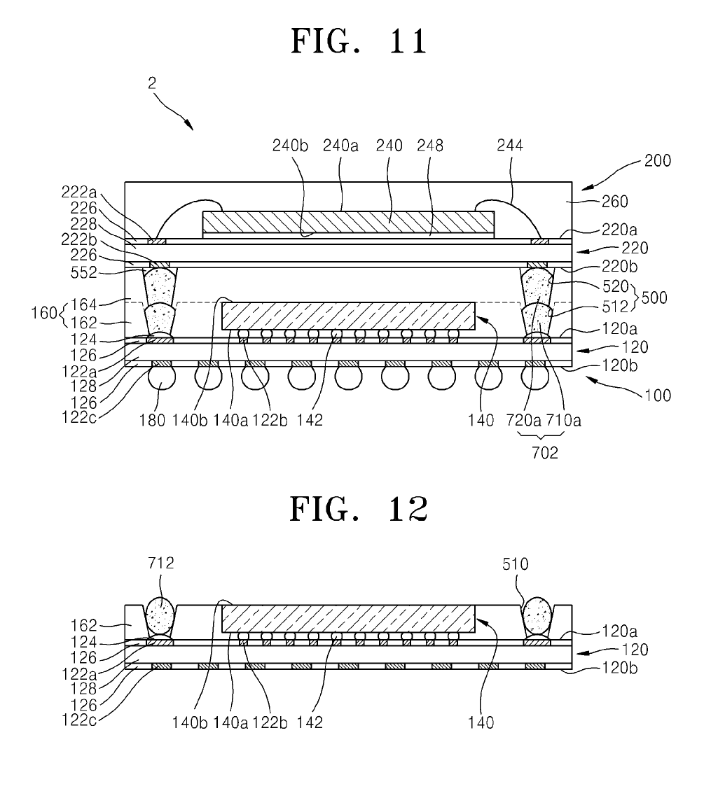

FIG. 11 is a schematic cross-sectional view of a semiconductor package 2 according to yet another embodiment of the inventive concepts.

Referring to FIG. 11, the semiconductor package 2 includes a lower package 100 and an upper package 200. After the second solder layer 720 illustrated in FIG. 8 is formed, or after the upper package 200 illustrated in FIG. 9 is attached onto the lower package 100, a reflowed second solder layer 720a is formed. The reflowed second layer 720a is formed through a reflow process in which heat is applied to the second solder layer 720. The reflowed second solder layer 720 may fill the entirety of a lower portion of a second section 520. Therefore, in the semiconductor package 2 illustrated in FIG. 11, a second vacancy 554 may be eliminated, such that only a first vacancy 552 exists along an upper edge portion of the second section 520.

Still further embodiments of the inventive concepts will now be illustrated and described, in which portions may be the same as in the descriptions of FIGS. 1 through 10 and redundant descriptions will be omitted. In addition, modifications to the following embodiments which are similar to that shown and described with respect to FIG. 11 (in which only the first vacancy 552 is formed), may likewise be made to the following embodiments.

FIG. 12 is a schematic cross-sectional view of a partially constructed semiconductor device, illustrating an operation of forming a first solder layer 712 according to another embodiment of the inventive concepts. More particularly, FIG. 12 represents an operation that may be performed after FIG. 3.

Referring to FIG. 12, a first solder layer 712 may be formed in a first through hole 510. The first solder layer 710 formed according to FIG. 4 may be formed by injecting a solder paste into the first through hole 510 using screen printing or solder jetting, or by picking and placing solder balls in the first through hole 510. However, the first solder layer 712 formed according to the embodiment of FIG. 12 may be formed by injecting a relatively large amount of solder paste into the first through hole 510, or by inserting relatively larger solder balls in the first through hole 510, as compared to the embodiment shown in FIG. 4.

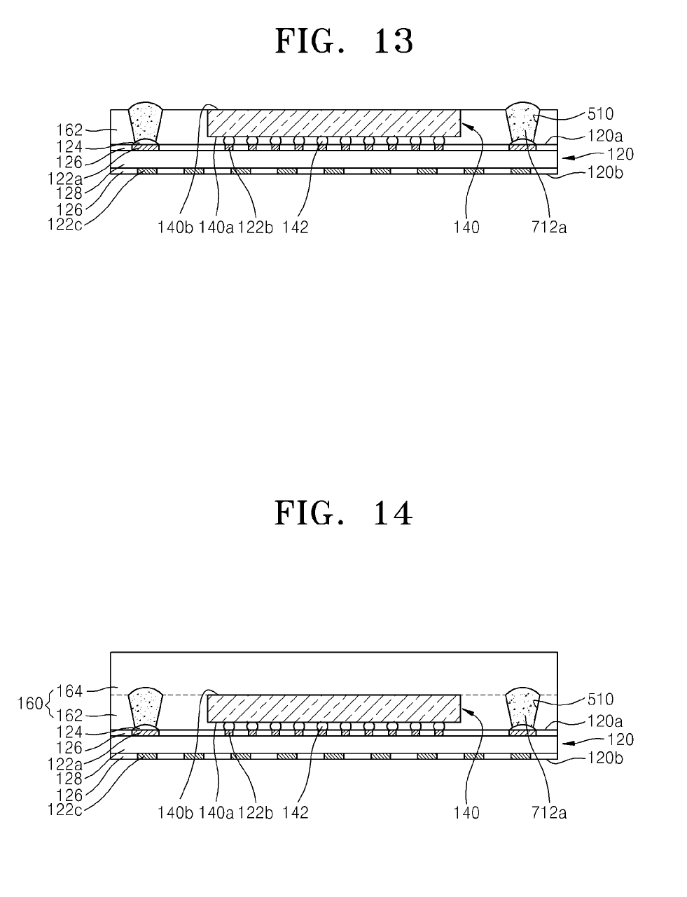

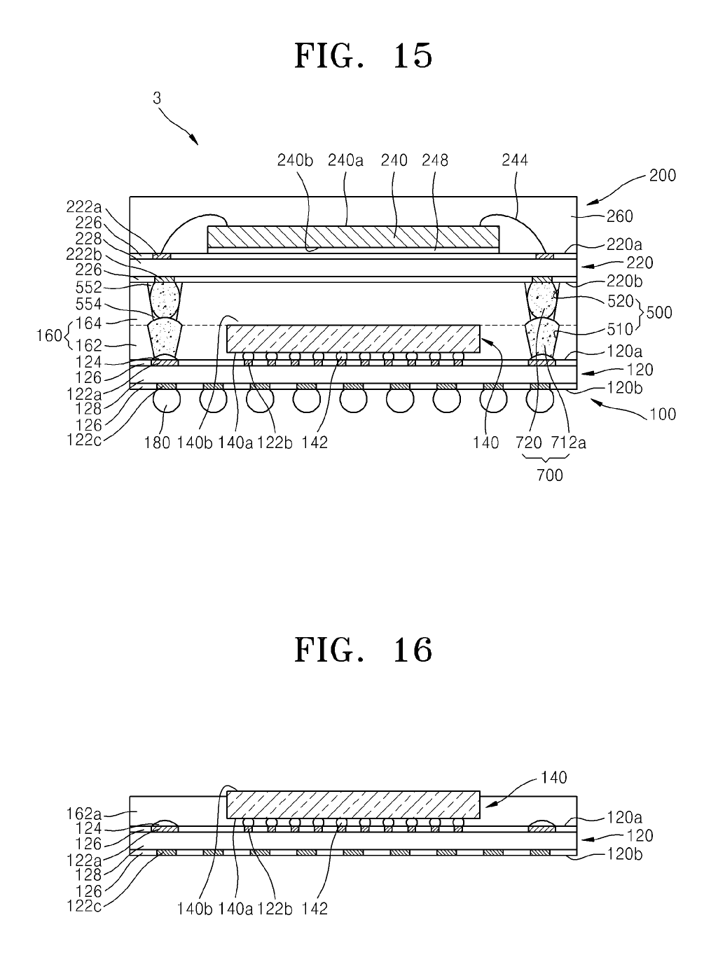

FIG. 13 is a schematic cross-sectional view of a partially constructed semiconductor device 3 of FIG. 15, illustrating an operation of reflowing the first solder layer 712 according to another embodiment of the inventive concepts.

Referring to FIG. 13, the reflowed first solder layer 712a is formed by applying heat to the first solder layer 712 to perform a reflow process. The reflowed first solder layer 712a may fill the entirety of the first through hole 510. A top surface of the reflowed first solder layer 712a may have the same height as the top surface of the first lower mold layer 162 or may have a convex shape that extends above the top surface due to surface tension.

FIG. 14 is a schematic cross-sectional view of a partially constructed semiconductor package 3 of FIG. 15, illustrating an operation of forming a second lower mold layer 164 on the embodiment of FIG. 13, according to another aspect of the inventive concepts.

Referring to FIG. 14, the second lower mold layer 164 can be formed on the first lower mold layer 162. The second lower mold layer 164 may be formed to cover both the reflowed first solder layer 712a and the lower semiconductor chip 140.

FIG. 15 is a schematic cross-sectional view of a semiconductor package 3 constructed according to another embodiment of the inventive concepts. More particularly, FIG. 15 illustrates a semiconductor package 3 formed by forming a second through hole and by mounting an upper package 200 on a lower package 100, as illustrated in FIGS. 7 through 10, after the operation of forming the second lower mold layer 164 is performed as illustrated in FIG. 14.

Referring to FIG. 15, after a second through hole 520 is formed by perforating the second lower mold layer 164 to expose the reflowed first solder layer 712a, a second solder layer 720 is formed in the second through hole 520. The first through hole 510 and the second through hole 520 may be referred to as a through via hole 502. In addition, the reflowed first solder layer 712a and the second solder layer 720 may be referred to as a solder layer 702. The semiconductor package 3 is then formed by mounting the upper package 200 on the lower mold layer 160.

In this case, since the first through hole 510 and the second through hole 520 each correspond to a section of the through via hole 500, the first through hole 510 may be referred to as a first section 510 and the second through hole 520 may be referred to as a second section 520. More particularly, since the entirety of the first through hole 510 is filled by the reflowed first solder layer 712a, the first through hole 510 itself may correspond to the first section 510. Thus, a horizontal cross-sectional area of the first section 510 is maximum at the top thereof, and the horizontal cross-sectional area gradually decreases from the top of the first section 510 to the bottom thereof.

When the top surface of the reflowed first solder layer 712a has the same height as the top surface of the first lower mold layer 162, and the top surface of the first lower mold layer 162 and the top surface 140b of the lower semiconductor chip 140 have the same height, the height of the first section 510 may be the same as the height of the lower semiconductor chip 140 with respect to the top surface 120a of the lower PCB 120.

FIG. 16 is a schematic cross-sectional view of a partially constructed semiconductor package 4 of FIG. 20 illustrating an operation of forming a first lower mold layer 162a according to another embodiment of the inventive concepts. More particularly, FIG. 16 illustrates operations performed after those illustrated in FIG. 1.

Referring FIG. 16, a first lower mold layer 162a may be formed above the lower PCB 120 so as to cover the lower PCB 120. The first lower mold layer 162a may be formed of EMC, for example. Unlike the previous embodiment of FIG. 2, the first lower mold layer 162a may be formed to expose the non-active face 140b of the lower semiconductor chip 140 and to cover only a part of sides of the lower semiconductor chip 140. Accordingly, the top surface of the first lower mold layer 162a may be lower than the non-active face 140b of the lower semiconductor chip 140.

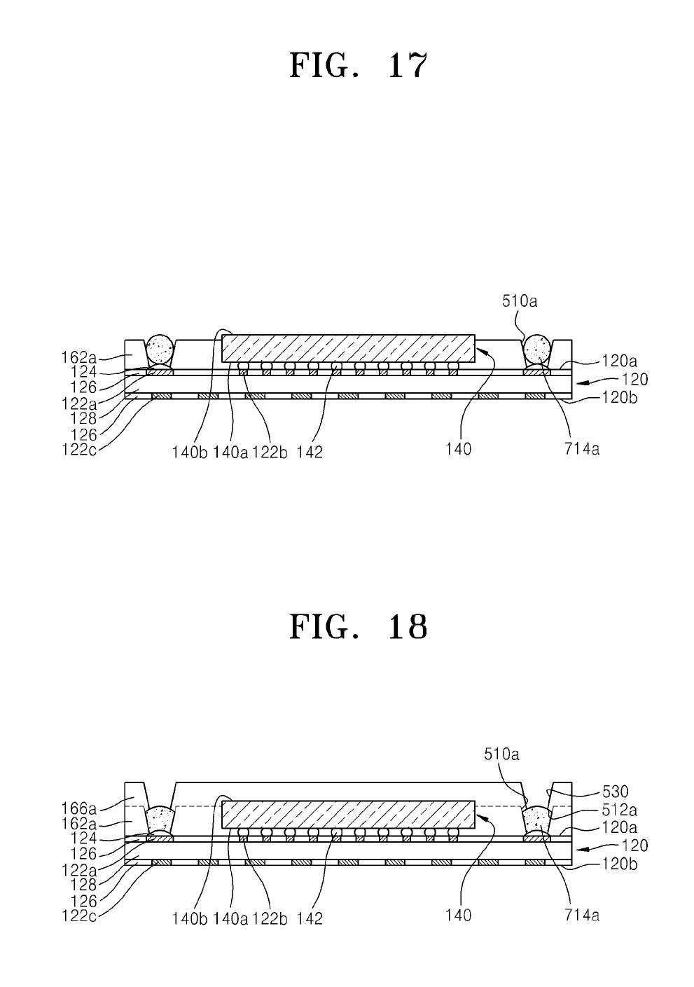

FIG. 17 is a schematic cross-sectional view of a partially constructed semiconductor package 4 of FIG. 20 illustrating an operation of forming a first through hole 510a and a first solder layer 714 in the partially constructed package of FIG. 16, according to an embodiment of the inventive concepts.

Referring to FIG. 17, a first through hole 510a is formed to perforate the first lower mold layer 162a, and a first solder layer 714 is then formed in the first through hole 510a.

FIG. 18 is a schematic cross-sectional view of a partially constructed semiconductor package 4 of FIG. 20, illustrating an operation of forming a third lower mold layer and a third through hole after the first solder layer 714 is formed as shown in FIG. 17, and then reflowed, according to an embodiment of the inventive concepts.

Referring to FIG. 18, a reflowed first solder layer 714a is formed by applying heat to the first solder layer 714 to perform a reflow process. The first solder layer 714a may fill only part of, or may fill the entirety of the first through hole 510a. A third lower mold layer 166 a may then be formed on the first lower mold layer 162a. The third lower mold layer 166a may be formed to cover all of the lower semiconductor chip 140. Alternatively, the third lower mold layer 166a may be formed to expose the top surface of the lower semiconductor chip 140, i.e., the non-active face 140a.

After the third lower mold layer 166a is formed on the first lower mold layer 162a, a third through hole 530 can be formed by perforating the third lower mold layer 166a to expose the reflowed first solder layer 714a. A portion of the first through hole 510 that is not filled by the first solder layer 714a may be filled by the third lower mold layer 166a, and a space that is formed by sidewalls of the first and third lower mold layers 162a and 166a that surround the reflowed first solder layer 714a may be referred to as a first through via hole 512a.

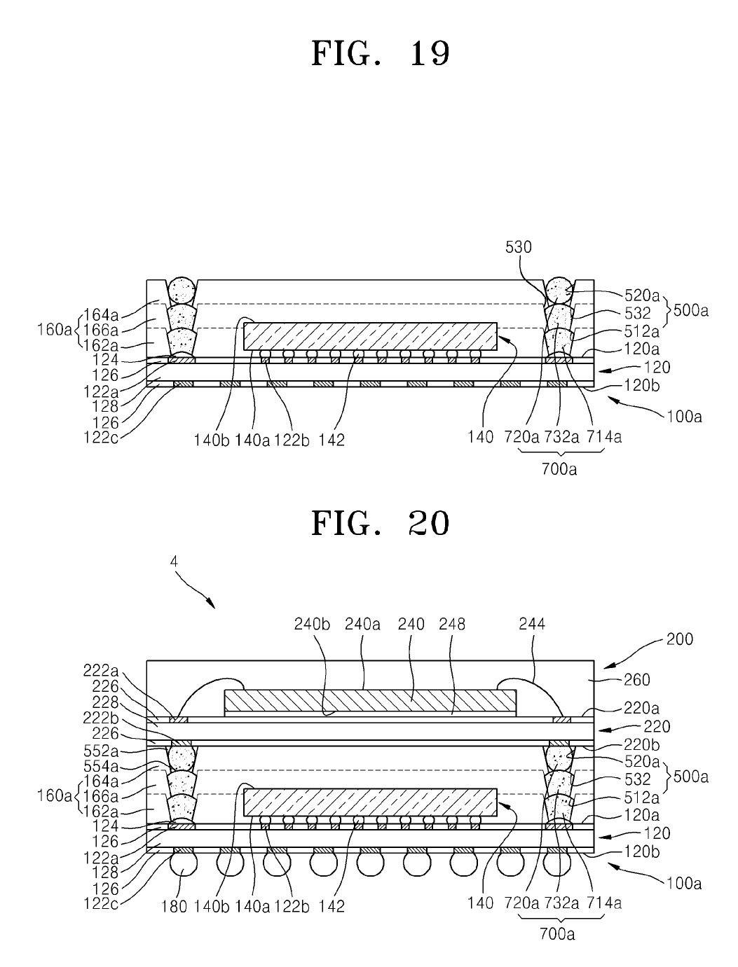

FIG. 19 is a schematic cross-sectional view of a partially constructed semiconductor package 4 of FIG. 20, illustrating an operation of forming a second lower mold layer 164a, a second through hole 520a, and a second solder layer 720a after a third solder layer 732 is formed and then reflowed in the third through hole 530, according to another embodiment of the inventive concepts.

Referring to FIG. 19, a reflowed third solder layer 732a is formed in the third through hole 530. An operation of forming the reflowed third solder layer 732a may be the same as the operation of forming the reflowed first solder layer 714a. After forming the reflowed third solder layer 732a, a second lower mold layer 164a may be formed on the third lower mold layer 166a, and a second through hole 520a may be formed to perforate the second lower mold layer 164a and expose the reflowed third solder layer 732a. The second solder layer 720a may then be formed in the second through hole 520a.

Since a portion of the third through hole 530 that is not filled by the third solder layer 730a may be filled by the second lower mold layer 146a, a space that is formed by sidewalls of the second and third lower mold layers 164a and 166a that surround the reflowed second solder layer 730a may be referred to as a third through via hole 532.

The first through via hole 512a, the third through via hole 532, and the second through hole 520a may collectively be referred to a through via hole 500a. In addition, the reflowed first solder layer 714a, the reflowed third solder layer 732a, and the second solder layer 720a may collectively be referred to as a solder layer 720a. In addition, the first through third lower mold layers 162a, 164a, and 166a may collectively be referred to as a lower mold layer 160a.

FIG. 20 is a schematic cross-sectional view of a semiconductor package 4 formed by mounting an upper package 200 on a lower package 100a, according to another embodiment of the inventive concepts.

Referring to FIG. 20, the semiconductor package 4 is formed by mounting the upper package 200 on the lower mold layer 160a. Unlike the semiconductor package 1 shown in FIG. 9, in which the solder layer 700 includes the reflowed first solder layer 710a and the second solder layer 720, the semiconductor package 4 further includes a reflowed third solder layer 732a arranged between the reflowed first solder layer 714a and the second solder layer 720a. Thus, unlike the embodiment in FIG. 9 where the solder layer 700 is formed in the through via hole 500 having a first section 512 and a second section 520, the semiconductor package 4 has an additional third section 532 arranged between the first section 512a and the second section 520a.

A cross-sectional area of the third section 532 may vary along the entire height of the third section 532, similar to the first section 512a.

The semiconductor package 4 may therefore include a lower package 100a, an upper package 200, and a solder layer 700a. The lower package 100a may include a lower PCB 120, a lower semiconductor chip 140 attached to the lower PCB 120, and a lower mold layer 160a. The lower mold layer 160a may be formed on the lower PCB 140 to surround the lower semiconductor chip 140 and have a through via hole 700a formed therein. The upper package 200 may be attached to the lower package 200a and may include an upper PCB 220, an upper semiconductor chip 240 attached to the upper PCB 220, and an upper mold layer 260. The upper mold layer 260 may be formed on the upper PCB 120 to surround the upper semiconductor chip 240. The solder layer 700a may connect the upper PCB 200 and the lower PCB 120 so as to electrically connect the upper package 200 and the lower package 100a.

The through via hole 500a may include a plurality of sections 512a, 532, and 520a that are connected together and perforate the lower mold layer 160a. A horizontal cross-sectional area of each of the plurality of sections 512a, 532, and 520a may increase from a bottom portion thereof toward a boundary between that section 512a, 532, or 520a and a connecting one of the section 532 or 520a.

The solder layer 700a may be formed through the through via hole 500a and may fill the entirety of the first section 512a directly adjacent the lower PCB 120. In addition, the solder layer 700a may fill the entirety of the third section 532.

A horizontal cross-sectional area of the second section 520a, which provides a top section, may gradually decrease from the top surface of the lower mold layer 160a toward the third section 532.

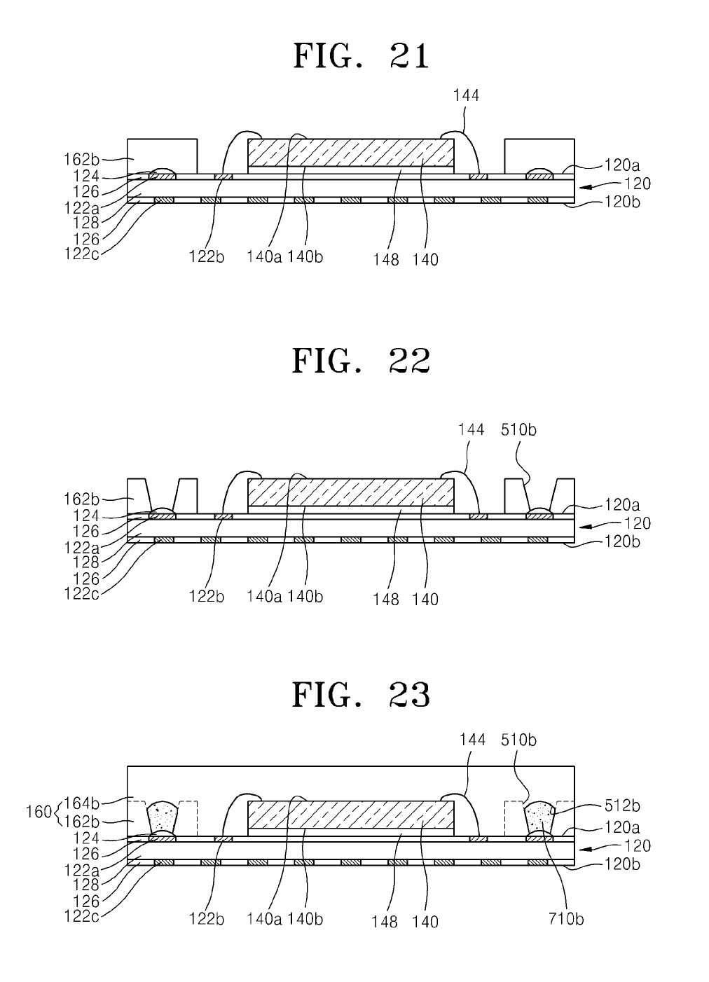

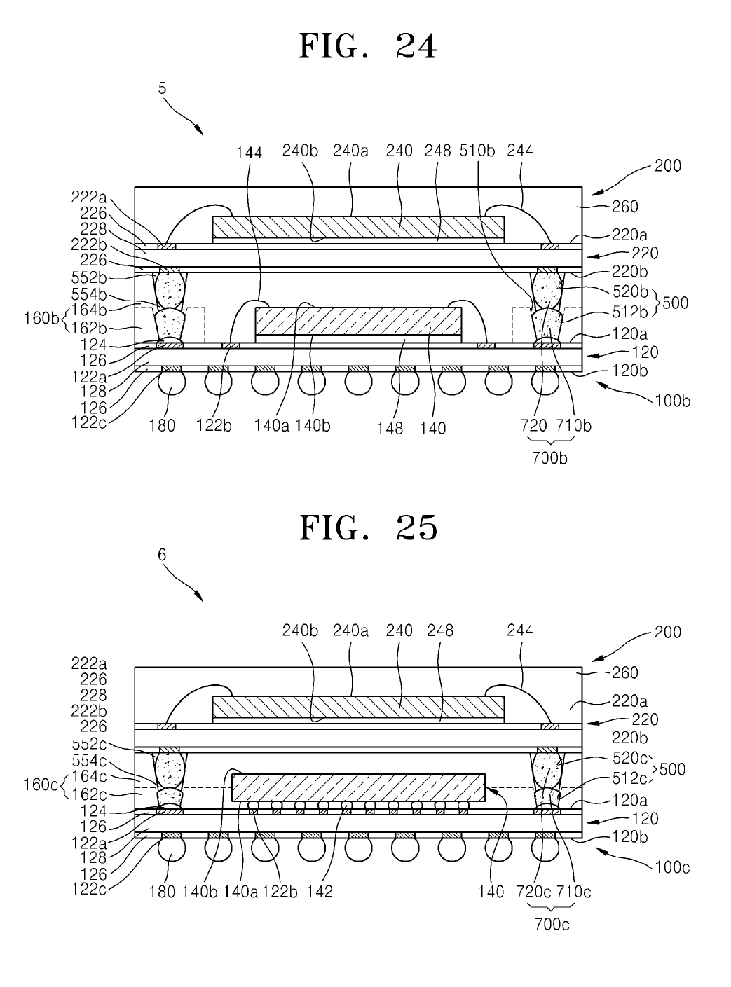

FIG. 21 is a schematic cross-sectional view of a partially constructed semiconductor package 5 of FIG. 24, illustrating an operation of forming a first lower mold layer after a lower semiconductor chip 140 is attached onto a lower PCB 120, according to another embodiment of the inventive concepts.

Referring to FIG. 21, a lower semiconductor chip 140 is attached onto a lower PCB 120. The lower semiconductor chip 140 may be mounted onto the lower PCB 120 such that a lower adhesive layer 148 is interposed between the lower semiconductor chip 140 and the lower PCB 120 with the non-active face 140b facing the lower PCB 120. The active face 140a of the lower semiconductor chip 140 in this embodiment may be referred to as a top surface of the lower semiconductor chip 140.

The lower PCB 120 may include a top surface 120a on which each of first and second lower connection pads 122a and 122b are formed, and a bottom surface on which a third lower connection pad 122c is formed. The first, second, and third lower connection pads 122a, 122b, and 122c are exposed by the solder register layer 126. The first and second lower connection pads 122a and 122b may be formed in an area of the top surface 120a of the lower PCB 120 outside an area covered by the lower semiconductor chip 140. Alternatively, the first lower connection pads 122a may be formed in an outer area, not covered by the lower semiconductor chip 140, while the second lower connection pads 122b may be formed in an area covered by the lower semiconductor chip 140, depending on the mounting method thereof.

The lower semiconductor chip 140 may be electrically connected to the lower PCB 120 through a wire bonding method using a lower bonding wire 144. The lower bonding wire 144 may be formed to connect a pad formed on the active face 140a of the lower semiconductor chip 140 and the second lower connection pad 122b formed on the top surface 120a of the lower PCB 120.

A first lower mold layer 162b may be formed on the lower PCB 120 so as to cover the first lower connection pad 122a, but not cover the second lower connection pad 122b, the lower semiconductor chip 140, and the lower bonding wire 144. The first lower mold layer 162b may be formed on the lower PCB 120 after the lower semiconductor chip 140 and the lower bonding wire 144 are attached onto the lower PCB 120. Alternatively, however, the first lower mold layer 162b can be formed first, before attaching the lower semiconductor chip 140 and the lower bonding wire 144 onto the lower PCB 120.

FIG. 22 is a schematic cross-sectional view of a partially constructed semiconductor package 5 of FIG. 24, illustrating an operation of forming a first through hole 510b according to another aspect of the inventive concepts.

Referring to FIG. 22, a first through hole 510b can be formed to penetrate through the first lower mold layer 162b. The first through hole 510b may, for instance, be formed by removing a part of the first lower mold layer 162b using an etching process or laser drilling, or it could be formed through molding using a die. The first through hole 510b may be formed to expose a portion of the lower PCB 120. For instance, the first through hole 510b may be formed to expose an adhesive solder layer 124 of the lower PCB 120.

FIG. 23 is a schematic cross-sectional view of a partially constructed semiconductor package 5 of FIG. 24, illustrating an operation of forming a second lower mold layer 164b after a first solder layer is formed and is reflowed, according to yet another aspect of the inventive concepts.

Referring to FIG. 23, a reflowed first solder layer 710b can be formed using a reflow process by applying heat to the first solder layer (not shown). The first solder layer 710b may fill only a part or all of the first through hole 510b.

Following the reflow process, a second lower mold layer 164b can be formed on the first lower mold layer 162b. The second lower mold layer 164b may, for instance, be formed to cover all of the reflowed first solder layer 710b, the lower semiconductor chip 140, and the lower bonding wire 144.

FIG. 24 is a schematic cross-sectional view of a semiconductor package 5, in which an upper package 200 is mounted on a lower package 100 after a second through hole 520b and a second solder layer 720b are formed, according to another aspect of the inventive concepts.

Referring to FIG. 24, the semiconductor package 5 can be formed by mounting the upper package 200 on the lower package 100 after the second through hole 520b and the second solder layer 720b are formed. The second through hole 520b and second solder layer 720b can be formed, for instance, as illustrated in FIGS. 7 through 9.

Unlike the semiconductor package 1 illustrated in FIG. 9, wherein the lower semiconductor chip 140 of the lower package 100 is attached onto the lower PCB 120 using a flip chip method, in the semiconductor package 5 of this embodiment, the lower semiconductor chip 140 of the lower package 100 is attached to the lower PCB 120 using a wire bonding method.

In addition, in the semiconductor package 1 illustrated in FIG. 9, the first lower mold layer 162 is formed to cover the entire exposed surface of the lower PCB 120. In the semiconductor package 5, illustrated in FIG. 24, however, the first lower mold layer 162b is formed only in an area in which the first lower connection pad 122a is formed, and is not formed in an area in which the second lower connection pad 122b is formed or in an area in which the lower semiconductor chip 140 is attached.

It should be understood, however, that the flip chip attaching method of the lower semiconductor chip 140 illustrated in FIG. 9 could used in conjunction with a first lower mold layer 162b as illustrated in FIG. 24. And, alternatively, the wire bonding attaching method illustrated in FIG. 24 could be used with the method of forming the first lower mold layer 162 as illustrated in FIG. 9.

FIG. 25 is a schematic cross-sectional view illustrating a semiconductor package 6 according to another embodiment of the inventive concepts.

Comparing the embodiments shown in FIGS. 9 and 25, in the semiconductor package 1 of FIG. 9, the top surface of the first lower mold layer 162 and the top surface of the lower semiconductor chip 140 have the same height, however, in the semiconductor package 6 of FIG. 25, the top surface of the first lower mold layer 162c is lower than the top surface of the lower semiconductor chip 140. According to the embodiment shown in FIG. 25, a portion of the lower mold layer 160c formed on the lower semiconductor chip 140 can be thinner so that the entire thickness of a lower package 100c may be reduced.

A height from the bottom to the top of a second section 520c may be larger than a height from the bottom to the top of a first section 512c. A horizontal cross-sectional area near the center of a second solder layer 720c may be larger than a horizontal cross-sectional area of the second solder layer 720c at its upper end. In addition, a horizontal cross-sectional area of a reflowed first solder layer 710c may be larger at its upper end than at its center.

Accordingly, when the height of the second section 520c is larger than the height of a first section 512c, the horizontal cross-sectional area of the upper portion of the second solder layer 720c may also be increased. By increasing the area of the second solder layer 720c at its upper portion, both the electrical connection and an adhesive force between the solder layer 700c and an upper package 200 may be improved.

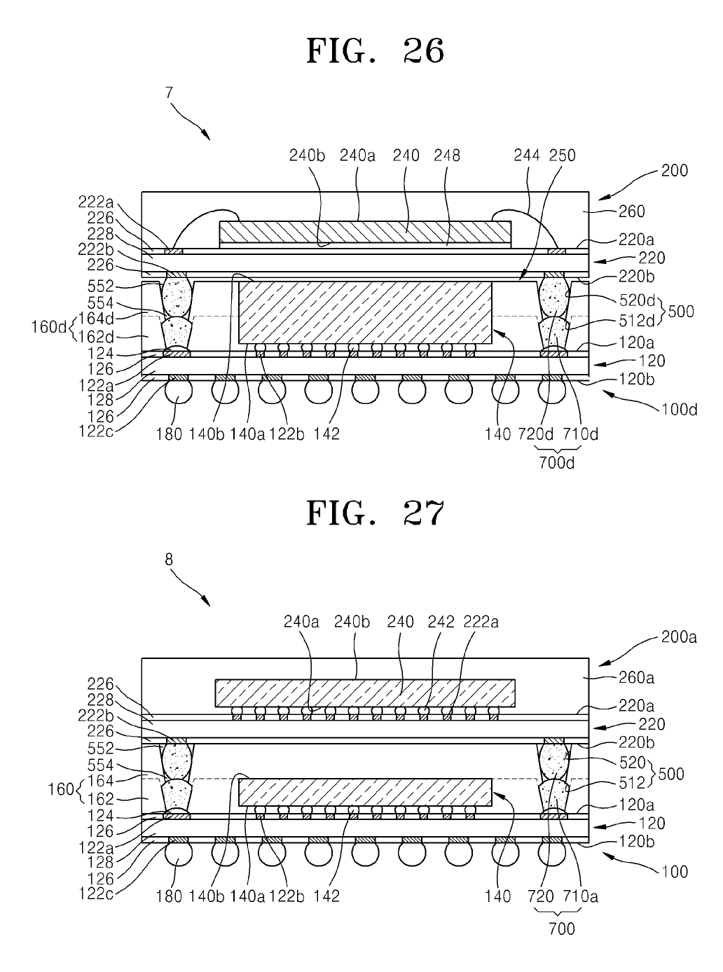

FIG. 26 is a schematic cross-sectional view of a semiconductor package 7 according to another embodiment of the inventive concepts.

Referring to FIG. 26, a semiconductor package 7 is formed by attaching an upper package 200 onto a lower package 100d. The lower package 100d may include a lower mold layer 160d, having first and second lower mold layers 162d and 164d which expose a top surface of a lower semiconductor package 140. The top surface of the lower semiconductor package 140 may be exposed, for instance, when, as illustrated in FIG. 26, the lower semiconductor chip 140 is thicker than the lower semiconductor chip of FIG. 9, or it may be exposed when the first and second lower mold layers 162d and 164d are thinner than the first and second lower mold layers 162 and 164 of FIG. 9.

The second solder layer 720d may protrude from the top surface of the lower mold layer 160d and the top surface of the lower semiconductor chip 140, such that the upper package 200 is attached onto the lower package 100d with a gap 250 formed between the upper package 200 and the lower package 100d. For instance, a gap may exist between the lower surface of the upper PCB 220 and the upper surface of the lower semiconductor chip 140 or the lower mold layer 140. Since the gap exposes the upper surface of the lower semiconductor chip 140 to ambient air, heat generated in the lower semiconductor chip 140 may be more easily dissipated from the semiconductor package 7.

FIG. 27 is a schematic cross-sectional view illustrating a semiconductor package 8 according to another embodiment of the inventive concepts.

Referring to FIG. 27, a semiconductor package 8 can be formed by attaching an upper package 200a onto a lower package 100. The upper package 200 can be constructed as illustrated in FIG. 9, with the upper semiconductor chip 240 attached onto the upper PCB 220 using a wire bonding method. Alternatively, as with the upper package 200a illustrated in FIG. 27, an upper semiconductor chip 240 can be attached onto an upper PCB 220 using a flip chip method.

It should also be understood that the upper package 200a, in which the upper semiconductor chip 240 is attached onto the upper PCB 220 using a flip chip method, may replace the upper package 200, in which the upper semiconductor chip 240 is attached onto the upper PCB 220 using a wire bonding method, in other embodiments of the inventive concepts.

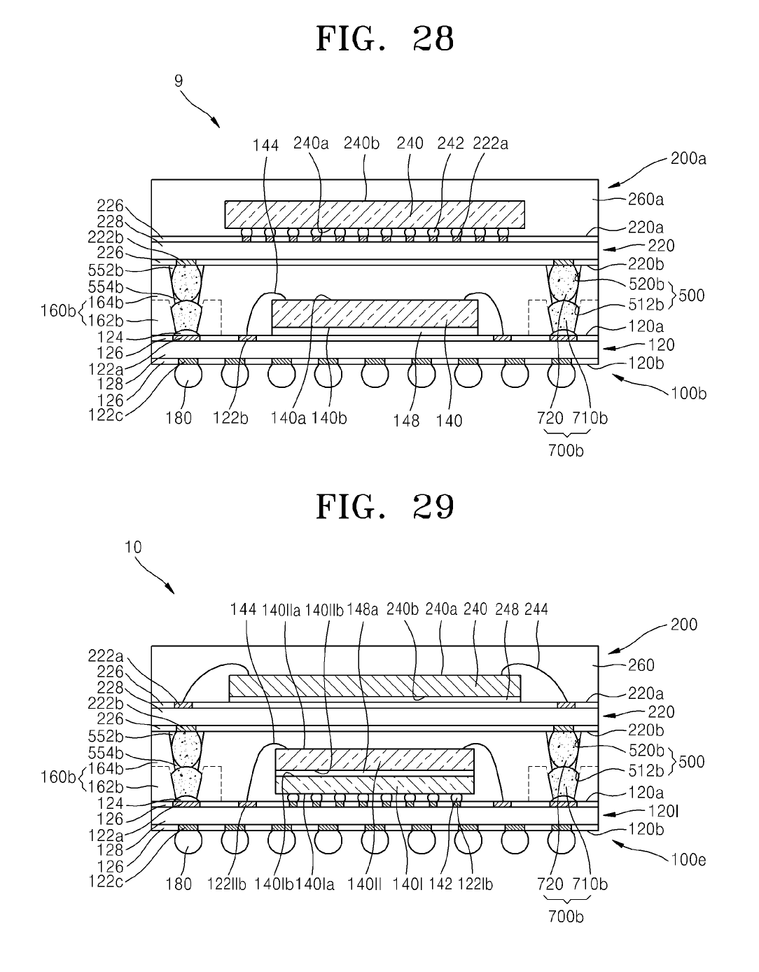

FIG. 28 is a schematic cross-sectional view illustrating a semiconductor package 9 according to another embodiment of the inventive concepts.

Referring to FIG. 28, a semiconductor package 9 can be formed by attaching an upper package 200a onto a lower package 100b. In the lower package 100b, a lower semiconductor chip 140 may be attached onto a lower PCB 120 using a wire bonding method, while an upper semiconductor chip 240 in the upper package 200a may be attached onto an upper PCB 220 using a flip chip method.

FIG. 29 is a schematic cross-sectional view illustrating a semiconductor package 10 according to another embodiment of the inventive concepts.

Referring to FIG. 29, a semiconductor package 10 can be formed by attaching an upper package 200 onto a lower package 100e. The lower package 100e may include a first lower semiconductor chip 140I and a second lower semiconductor chip 140II. A lower PCB 120I may include a second lower connection first pad 1221b and a second lower connection second pad 122IIb. The first lower semiconductor chip 140I and the second lower semiconductor chip 140II may be sequentially stacked on the lower PCB 120I, with the second lower semiconductor chip 140II attached onto the first lower semiconductor chip 140I using a lower adhesive layer 148a. The first lower semiconductor chip 140I may be electrically connected to the lower PCB 120I via the second lower connection first pad 1221b using a flip chip method. The second lower semiconductor chip 140II may be electrically connected to the lower PCB 120I via the second lower connection second pad 122IIb using a wire bonding method. The first lower semiconductor chip 140I may be stacked on the lower PCB 120I so that an active face 140Ia faces the lower PCB 120I. The second lower semiconductor chip 140II may be stacked on the first lower semiconductor chip 140I so that a non-active face 140IIb may face the first lower semiconductor chip 140I and the lower PCB 120I.

In FIG. 29, two semiconductor chips, i.e., the first and second lower semiconductor chips 140I and 140II are stacked on the lower PCB 120I. However, aspects of the inventive concepts are not limited to this particular embodiment. For instance, three or more semiconductor chips may be stacked and may be electrically connected to the lower PCB 120I by selectively using a flip chip method, and/or a wire bonding method, or other desired connection method.

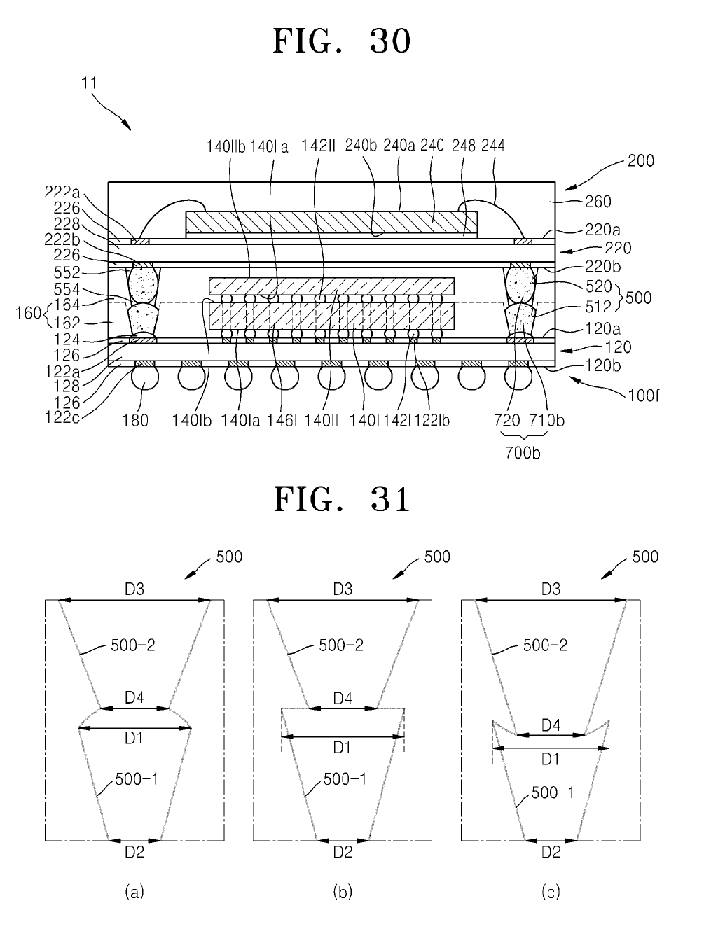

FIG. 30 is a schematic cross-sectional view of a semiconductor package 11 according to another embodiment of the inventive concepts.

Referring to FIG. 30, a semiconductor package 11 can be formed by attaching an upper package 200 onto a lower package 100f. The lower package 100f may include a first lower semiconductor chip 140I and a second lower semiconductor chip 140II. The first lower semiconductor chip 140I and the second lower semiconductor chip 140II may be sequentially stacked on a lower PCB 120. The first lower semiconductor chip 140I may be electrically connected to the lower PCB 120 via the second lower connection pad 122b using a flip chip method. The second lower semiconductor chip 140II may be electrically connected to the lower PCB 120 via a through electrode 146I that extends through the first lower semiconductor chip 140I. The first lower semiconductor chip 140I and the second lower semiconductor chip 140II may be stacked on the lower PCB 120 so that all of the active faces 140Ia and 140IIa face the lower PCB 120.

Although, in FIG. 30, two semiconductor chips, i.e., the first and second lower semiconductor chips 140I and 140II, are stacked on the lower PCB 120, the inventive concepts are not limited thereto. For instance, three or more semiconductor chips may be electrically connected to the lower PCB 120 using a through silicon via (TSV) method that uses a through electrode.

FIG. 31 provides schematic cross-sectional views of various potential configurations of through via holes 500 according to certain embodiments of the inventive concepts.

Referring to FIG. 31, each of the through via holes 500 may have a configuration in which a first via hole 500-1 and a second via hole 500-2 combine together to form the through via hole 500. For example, the first via hole 500-1 may be the same as or similar to the first through hole 510 formed in FIG. 3, or a part thereof. Alternatively, the first via hole 500-1 may be the same as or similar to the first through hole 512 illustrated in FIG. 9 or a part thereof. The second via hole 500-2 may be the same as or similar to the second through hole 510 formed in FIG. 7 or a part thereof.

Although, in one embodiment, the through via hole 500 can be formed by combining the first through hole 510 and the second through hole 520 as illustrated in FIGS. 3 and 7, respectively, due to the reflowed first solder layer 710a as illustrated in FIG. 5, the second lower mold layer 164 illustrated in FIG. 6, and the second solder layer 720 illustrated in FIG. 8, the cross-sectional shapes of the first through hole 510 and the second through hole 520 may be modified.

As illustrated in FIG. 31, each of the first via holes 500-1 and the second via holes 500-2 can correspond to a portion of the first through hole 510 and the second through hole 520, respectively, as illustrated in FIGS. 3 and 7. Although the overall shapes of the first and second via holes 500-1 and 500-2 are generally maintained in the subsequent processes, the shape of a portion of the through via hole 500 where the first via hole 500-1 and the second via hole 500-2 meet, may vary depending on the manufacturing processes performed. For instance, the shape at the junction may be modified in various ways by the reflowed first solder layer 710a illustrated in FIG. 5, the second lower mold layer 164 illustrated in FIG. 6, and the second solder layer 720 illustrated in FIG. 8.

In each of the embodiments ((a), (b), and (c)) shown in FIG. 31, a first, top diameter D1 of the first via hole 500-1 may be larger than a second, bottom diameter D2 of the first via hole 500-1. The diameter of the first via hole 500-1 may also continuously decrease from the top to the bottom thereof. Thus, in these embodiments, a horizontal cross-sectional area of the first via hole 500-1 continuously decreases from the top to the bottom. A third, top diameter D3 of the second via hole 500-2 may also be larger than a fourth, bottom diameter D4 of the second via hole 500-2. As with the first via hole 500-1, the diameter of the second via hole 500-2 may continuously decrease from the top diameter D3 to the bottom diameter D4. Thus, a horizontal cross-sectional area of the second via hole 500-2 may also continuously decrease from the upper portion to the bottom. In addition, the first diameter D1 of the first via hole 500-1 may be larger than the fourth diameter D4 of the second via hole 500-2. Accordingly, a relationship between the diameters of the through holes may be represented as follows: (D1>D2, D3>D4, D1>D4).

Each of the various embodiments will now be described separately in more detail, particularly with respect to the interface between the first and second via holes 500-1 and 500-2. Referring first to embodiment (a) in FIG. 31, the through via hole 500 can include a first via hole 500-1 and a second via hole 500-2. A bottom diameter D4 of the second via hole 500-2 may be higher than a top diameter D1 of the first via hole 500-1. An interface between the second via hole 500-2 and the first via hole 500-1 (i.e., between D4 and D1) can be a gradual increase in diameter, and can have a convex shape in a cross-sectional side view.

In a second embodiment (b), shown in FIG. 31, the through via hole 500 can again have a first via hole 500-1 and a second via hole 500-2. In this embodiment, however, the bottom diameter D4 of the second via hole 500-2 may be arranged at substantially the same height as the top diameter D1 of the first via hole 500-1.

In a third embodiment (c) of FIG. 31, the through via hole 500 again includes a first via hole 500-1 arranged substantially below a second via hole 500-2. In this embodiment, however, the bottom diameter D4 of the second via hole 500-2 may be arranged at a height lower than the top diameter D1 of the first via hole 500-1. A cross-sectional shape of the transition between the top diameter D1 of the first via hole 500-1 and the bottom diameter D4 of the second via hole D4 can, for instance, be a concave shape.

The first embodiment (a) of the through via hole 500 may, for instance, occur when the reflowed first solder layer 720a (illustrated in FIG. 5) has a convex upper surface due to surface tension. The second embodiment (b) of the through via hole 500 may occur, for instance, when the reflowed first solder layer 720a (formed as described with reference to FIG. 5) has a flat upper surface. The third embodiment (c) of the through via hole 500 may occur, however, when the reflowed first solder layer 720a (again formed as described with reference to FIG. 5) has a concave upper surface due to surface tension.

The shape of the through via hole 500 may depend, for instance, on the amount of the first solder layer 710 formed as described with reference to FIG. 4. When the amount of the first solder layer 710 formed as illustrated in FIG. 4 is relatively large, for instance, the shape of the through via hole 500 may be as shown in embodiment (a) of FIG. 31. When the amount of the first solder layer 710 is relatively small, however, the shape of the through via hole 500 may be as illustrated in embodiment (c) of FIG. 31. Finally, when the amount of the first solder layer 710 is average, the shape of the through via hole 500 may be as illustrated in embodiment (b) of FIG. 31.

In other words, the through via hole 500 may have a diameter (and corresponding horizontal cross-sectional area) that gradually decreases from a top thereof toward a center thereof, that then increases at an interface between a first and second via hole 500-1 and 500-2, and then gradually decreases from the center towards a bottom thereof. The shape of the through via hole 500 at an interface between the two via holes (or segments), may vary depending on the amount of solder used for the first solder layer 710 (see FIG. 4). For instance, the shape of the interface can be as illustrated in the first through third embodiments (a), (b), and (c) of the through via hole 500 of FIG. 31.

In addition, it should be noted that although only two segments (or through via holes) are shown combined in FIG. 31, three or more segments could also be combined in a similar manner according to the inventive concepts. Accordingly, although only one interface is illustrated in embodiments (a), (b), and (c) of FIG. 31, two or more interfaces could be present. The shape of each of the interfaces could be the same as one or more of the other interfaces, or the shapes of the interfaces could be different from one another depending on the amount of solder used for each of the corresponding solder layers.

In summary, when a through hole perforating a lower mold layer is formed as in the conventional art using a one-time etching process, a laser drilling method, or a molding method using a die, a horizontal cross-sectional area of the through hole may continuously decrease from a top to a bottom thereof. In such circumstances, in order for a solder layer formed in the through hole to be electrically connected to a lower PCB and to guarantee reliability of a semiconductor package, a horizontal cross-sectional area of the bottom of the through hole must be sufficiently large. In order to provide a sufficiently large bottom area, a horizontal cross-sectional area of a top of the through hole must be relatively large, since the cross-sectional area gradually decreases along the height of the lower mold layer. According to the conventional art, it is therefore difficult to implement through holes with a fine pitch, and when the number of solder layers (vias) for connecting an upper package and a lower package increase, as in a wide input/output (I/O) technology, the area and volume of the semiconductor package may also increase. However, when a through hole is formed in multiple segments, as in the embodiments of the inventive concepts shown and described herein, a horizontal cross-sectional area of a top of the through hole may be minimized Thus, solder layers (vias) for connecting the lower package to the lower PCB may be implemented having a fine pitch, and may also be applied in wide I/O technology applications without increasing the area and volume of the semiconductor package.

It should be understood that semiconductor packages according to the inventive concepts may be readily implemented using all different combinations of the lower packages 100, 100a, 100b, 100c, 100d, 100e, and 100f with the upper packages 200 and 200a illustrated in FIGS. 9, 11, 15, 20, and 24 through 30. The inventive concepts are therefore not limited to the specific embodiments of the semiconductor packages 1, 2, 3, 4, 5, 6, 7, 8, 9, 10, and 11 illustrated in the figures. In addition, the upper packages 200 and 200a may be formed to include a plurality of upper semiconductor chips, similar to the lower packages 100e and 100f illustrated in FIGS. 29 and 30. Furthermore, the features of each of the semiconductor packages 1, 2, 3, 4, 5, 6, 7, 8, 9, 10, and 11 described with reference to FIGS. 9, 11, 15, 20, and 24 through 30 may also be applied to the semiconductor packages of the other embodiments.

While the inventive concepts have been particularly shown and described with reference to exemplary embodiments thereof, it will be understood that various changes in form and details may be made therein without departing from the spirit and scope of the following claims.

What is claimed is:

1. A semiconductor package comprising:
a lower printed circuit board (PCB) having a top surface onto which at least one lower semiconductor chip is attached;
an upper printed circuit board (PCB) having a surface onto which at least one upper semiconductor chip is attached;
a lower mold layer formed on the top surface of the lower printed circuit board (PCB) so as to be disposed between the lower printed circuit board (PCB) and the upper printed circuit board (PCB);
a through via hole comprising a first section formed in the lower mold layer and a second section formed on the first section, the through via hole penetrating through the lower mold layer; and
a solder layer formed in the through via hole and electrically connecting the upper printed circuit board (PCB) and the lower printed circuit board (PCB),
wherein a horizontal cross-sectional area of the first section varies along the entire height of the first section, and
a horizontal cross-sectional area of the second section gradually decreases from a top portion thereof toward a bottom portion thereof.

2. The semiconductor package of claim 1, wherein a horizontal cross-sectional area of the first section is greatest at a top portion thereof, and wherein the horizontal cross-sectional area of the first section gradually decreases from the top portion thereof to a bottom portion thereof.

3. The semiconductor package of claim 1, wherein the horizontal cross-sectional area of the first section gradually increases at an interface between the first section and the second section and then gradually decreases toward the bottom of the first section.

4. The semiconductor package of claim 1, wherein a horizontal cross-sectional area of the first section is smallest at the bottom of the first section.

5. The semiconductor package of claim 1, wherein the solder layer fills substantially all of the first section.

6. The semiconductor package of claim 1, wherein the solder layer fills only a portion of the second section.

7. The semiconductor package of claim 6, wherein a vacancy is formed in the second section along an upper edge portion of the solder layer.

8. The semiconductor package of claim 7, wherein a second vacancy is formed in the second section along a lower edge portion of the solder layer.

9. The semiconductor package of claim 1, wherein the through via hole further comprises at least one third section disposed between the first section and the second section, wherein the at least one third section is filled by the solder layer, and wherein a horizontal cross-sectional area of the at least one third section varies over substantially an entire height of the at least one third segment space.

10. The semiconductor package of claim 1, wherein a height of a top of the first section is substantially the same as a height of the top surface of the at least one lower semiconductor chip with respect to the top surface of the lower printed circuit board (PCB).

11. The semiconductor package of claim 1, wherein at least one lower semiconductor chip and the lower printed circuit board (PCB), or at least one upper semiconductor chip and the upper printed circuit board (PCB) are electrically connected using a wire bonding method or a flip chip method.

12. The semiconductor package of claim 1, wherein the at least one lower semiconductor chip comprises a plurality of lower semiconductor chips,
wherein the plurality of lower semiconductor chips comprise a first lower semiconductor chip and a second lower semiconductor chip stacked on the first lower semiconductor chip, and
wherein the second lower semiconductor chip is electrically connected to the lower printed circuit board (PCB) via a through electrode extending through the first lower semiconductor chip.

13. The semiconductor package of claim 1, wherein a top surface of the at least one lower semiconductor chip is exposed by the lower mold layer.

14. The semiconductor package of claim 13, wherein the lower mold layer and the upper printed circuit board (PCB) are spaced apart from each other so that a gap exists between the lower mold layer and the upper printed circuit board (PCB).

15. A semiconductor package comprising:
a lower package comprising a lower printed circuit board (PCB), at least one lower semiconductor chip attached to the lower printed circuit board (PCB), and a lower mold layer formed on the lower printed circuit board (PCB), surrounding at least a portion of the at least one lower semiconductor chip and having a through via hole formed therein;
an upper package attached onto the lower package and comprising an upper printed circuit board (PCB), at least one upper semiconductor chip attached onto the upper printed circuit board (PCB), and an upper mold layer formed on the upper printed circuit board (PCB) and surrounding the at least one upper semiconductor chip; and
a solder layer electrically connecting the upper printed circuit board (PCB) and the lower printed circuit board (PCB),
wherein the through via hole comprises a plurality of sections connected together to extend through the lower mold layer, and
wherein a horizontal cross-sectional area of a top portion of at least one of the plurality of sections is greater than a horizontal cross-sectional area of a bottom portion of the section arranged immediately above that section, and
wherein the solder layer extends through the through via hole and fills substantially all of a section arranged adjacent to the lower printed circuit board (PCB), and
wherein a horizontal cross-sectional area of at least one of the sections gradually decreases from a top surface thereof toward an inside portion of the lower mold layer.

16. A semiconductor package comprising:
a lower package comprising a lower printed circuit board (PCB), at least one lower semiconductor chip attached onto the lower printed circuit board (PCB), and a lower mold layer formed on the lower printed circuit board (PCB), surrounding at least a part of the at least one lower semiconductor chip and having a through via hole formed therein;
an upper package attached onto the lower package and comprising an upper printed circuit board (PCB), at least one upper semiconductor chip attached onto the upper printed circuit board (PCB), and an upper mold layer formed on the upper printed circuit board (PCB) and surrounding the at least one upper semiconductor chip; and
a solder layer electrically connecting the upper printed circuit board (PCB) and the lower printed circuit board (PCB),
wherein the through via hole extends through the lower mold layer and comprises a cross-sectional area that varies along its height and comprises a plurality of different diameters including at least a first diameter, a second diameter, a third diameter, and a fourth diameter, and
wherein the cross-sectional area comprises the first diameter near a top of the via hole and wherein the cross-sectional area tapers inwardly towards an interior of the lower mold layer until it comprises the second diameter, said second diameter being smaller than the first diameter, and
wherein the cross-sectional area of the through via hole expands from the second diameter to the third diameter, said third diameter being larger than the second diameter, and
wherein the cross-sectional area tapers gradually from the third diameter to the fourth diameter, said fourth diameter being smaller than the third diameter and being arranged near a bottom of the through via hole.

17. The semiconductor package of claim 16, wherein the cross-sectional area of the through via hole expands gradually in a downward direction from the second diameter to the third diameter, and wherein a sidewall of the through via hole has a somewhat convex cross-sectional shape between the second diameter and the third diameter.

18. The semiconductor package of claim 16, wherein the cross-sectional area of the through via expands substantially immediately from the second diameter to the third diameter, such that a sidewall of the through via hole has a substantially flat horizontal cross-sectional shape between the second diameter and the third diameter.

19. The semiconductor package of claim 16, wherein an outermost diameter of the through via hole expands gradually in an upward direction from the second diameter to the third diameter, such that a sidewall of the through via has a somewhat concave cross-sectional shape between the second diameter and the third diameter.

20. The semiconductor package of claim 16, wherein the solder layer fills substantially all of the area of the through via hole between the third diameter and the fourth diameter, but fills less than the entire area of the through via hole between the first diameter and the second diameter.
